(19) United States
(12) Patent Application Publication
(10) Pub. No.: US 2026/0303105 A1
(43) Pub. Date: Oct. 1, 2026

(54) DIGITAL-TO-ANALOG CONVERTER

(71) Applicant: STMicroelectronics International N.V., Geneva (CH)

(72) Inventors: Vincent Binet, Aix en Provence (FR); Michel Cuenca, Septemes les Vallons (FR)

(21) Appl. No.: 19/578,462

(22) Filed: Mar. 25, 2026

(30) Foreign Application Priority Data
Mar. 31, 2025 (FR) FR2503315

(51) Int. Cl. H03M 1/06

(52) U.S. Cl. CPC H03M 1/06

(57) ABSTRACT

The present description concerns a digital-to-analog converter receiving a digital control code. For each bit of the digital code, a voltage control circuit receives the bit and partly determines an output voltage value based on the bit value. For each bit of the digital code, a transmission path receives the bit and transmits it to the corresponding control circuit via a transmit circuit controlling a time of transmission of the bit via this path, so that, for at least one change in the digital code from a first code controlling a first output voltage value to a second code controlling a second output voltage value, the control circuits receive, between the first and second codes, a third code causing a voltage pulse of desired polarity on the output voltage.

### CROSS-REFERENCE TO RELATED APPLICATIONS

This application claims the priority benefit of French Patent Application No. 2503315 filed on Mar. 31, 2025, entitled “Digital-to-Analog Converter,” which application is hereby incorporated herein by reference to the maximum extent allowable by law.

### TECHNICAL FIELD

The present disclosure generally concerns electronic circuits, and more particularly digital-to-analog converters.

### BACKGROUND

Digital-to-analog converters are used in a large number of known electronic systems or circuits. A digital-to-analog converter receives a digital voltage control code, that is, a digital word over a plurality of bits, and delivers an analog output signal, for example, a voltage, having a value determined by the value of the digital control code, that is, by the value ‘1’ or ‘0’ of each bit of the digital code.

Known digital-to-analog converters suffer from various disadvantages.

For example, known digital-to-analog converters may have an output voltage having voltage glitches when the output voltage changes value as a response to a change in the control code received by the converter. Such voltage glitches can lead to a malfunction of the electronic system or circuit comprising the converter.

### SUMMARY

There exists a need to overcome all or part of the disadvantages of known digital-to-analog converters.

An embodiment overcomes all or part of the disadvantages of known digital-to-analog converters.

An embodiment provides a digital-to-analog converter comprising: an input configured to receive a digital code for controlling an output voltage of the converter;
for each bit of the digital code, a voltage control circuit configured to receive the bit and to partly determine a value of the output voltage based on a value of the bit; and
for each bit of the digital code, a transmission path configured to receive the bit and transmit it to the corresponding voltage control circuit,
wherein each transmission path comprises a transmit circuit configured to control a time of transmission of a bit by the path; and
wherein the transmit circuits are configured so that, for at least one change in the digital code from a first code controlling a first value of the output voltage to a second code controlling a second value of the output voltage, the voltage control circuits receive, between the first code and the second code, a third code causing a voltage pulse of desired polarity on the output voltage.

According to an embodiment, each transmit circuit is selectively activatable.

According to an embodiment, the first and second codes are immediately successive codes from a set of digital codes that the converter is configured to receive.

According to an embodiment, the converter comprises a first binary-type digital-to-analog converter configured to be controlled by part of the bits, preferably least significant bits, of the digital code received by the converter, and a second thermometric-type digital-to-analog converter configured to be controlled by the other part of the bits, preferably most significant bits, of the digital code received by the converter.

According to an embodiment, the at least one change in the digital code comprises each change from a first code to a second code involving a change in value of at least two bits between the first code and the second code.

According to an embodiment, the transmit circuits are configured so that, on each code change from a first code to a second code involving a change in value of at least two bits between the first code and the second code, the bit(s) having weights lower than the weight of the most significant of the at least two bits are transmitted rapidly to the control circuits than the other bit(s) of the code.

According to an embodiment, on each code change from a first code to a second code involving a change in value of at least two bits between the first code and the second code:
the least significant bit(s) of the third code correspond to the bits having weights lower than weight of the most significant of the at least two bits;
the most significant bit(s) of the third code correspond to the bits having a weight equal to or greater than that of the most significant of the at least two bits;
the least significant bit(s) of the third code of the code change have values equal to those of the corresponding bits of the second code; and
the most significant bit(s) of the third code of the code change have values equal to those of the corresponding bits of the first code.

According to an embodiment:
when the first value is greater than the second value, the voltage pulse has a positive polarity; and/or
when the first value is lower than the second value, the voltage pulse has a negative polarity.

According to an embodiment, each transmit circuit is configured to receive a clock signal and comprises:
a synchronous flip-flop having a data input configured to receive the bit to be transmitted via the path comprising the transmit circuit, and an output supplying the transmitted bit to the corresponding control circuit; and
a first circuit configured to transmit the clock signal to a clock input of the flip-flop with a transmission time determining a time of transmission of the bit by the transmit circuit.

According to an embodiment, each transmit circuit comprises:
a first inverter having an output and an input configured to receive the bit to be transmitted via the path comprising the transmit circuit;
a second inverter having an input connected to the output of the first inverter and an output configured to supply the transmitted bit to the corresponding control circuit;
a first PMOS transistor and a second PMOS transistor in series between a high power supply potential and the output of the first inverter; and
a first NMOS transistor and a second NMOS transistor in series between the output of the first inverter and a low power supply potential,
wherein:
a gate of the first PMOS transistor and a gate of the first NMOS transistor are each configured to receive the bit to be transmitted; and
a gate of the second PMOS transistor and a gate of the second NMOS transistor are each configured to receive a delayed binary complement of the bit which has a weight immediately lower than the weight of the bit to be transmitted.

Another embodiment provides an electronic system comprising:
a converter such as defined hereabove; and
a comparator having one input configured to receive a reference voltage, and another input configured to receive the output voltage of the converter.

According to an embodiment, the system comprises a control circuit configured to supply successive digital codes to the converter, so that the output voltage of the converter is either an increasing voltage ramp or a decreasing voltage ramp.

### BRIEF DESCRIPTION OF THE DRAWINGS

The foregoing features and advantages, as well as others, will be described in detail in the rest of the disclosure of specific embodiments given as an illustration and not limitation with reference to the accompanying drawings, in which:

FIG. 1 shows, schematically and in the form of blocks, an example of a digital-to-analog converter of the type to which the described embodiments apply;

FIG. 2 illustrates by means of curves an example of a problematic operation of the converter of FIG. 1;

FIG. 3 illustrates by means of curves another example of a problematic operation of the converter of FIG. 1;

FIG. 4 shows, schematically and in the form of blocks, an example of a system comprising a digital-to-analog converter;

FIG. 5 illustrates by means of curves an example of a problematic operation of the system of FIG. 4 comprising the converter of FIG. 1; and

FIG. 6 shows, schematically and in the form of blocks, an example of a digital-to-analog converter;

FIG. 7 illustrates by means of curves an example of operation of the converter of FIG. 6;

FIG. 8 shows, schematically and in the form of blocks, a more detailed example of embodiment of the digital-to-analog converter of FIG. 6;

FIG. 9 shows a more detailed example of an embodiment of a bit control or transmit circuit implemented in the digital-to-analog converter of FIG. 8; and

FIG. 10 shows, schematically and in the form of blocks, another more detailed example of embodiment of the digital-to-analog converter of FIG. 6.

### DETAILED DESCRIPTION OF ILLUSTRATIVE EMBODIMENTS

The same elements have been designated by the same references in the various figures. In particular, structural and/or functional elements common to the different embodiments may have the same references and may have identical structural, dimensional and material properties.

For the sake of clarity, only those steps and elements that are useful for understanding the described embodiments have been shown and are described in detail. In particular, the various electronic circuits, electronic systems, and electronic applications in which a digital-to-analog converter may be provided have not been detailed, the embodiments and variants described herein being compatible with these known circuits, systems, and applications.

Unless specified otherwise, when reference is made to elements connected together, this signifies a direct connection without any intermediate elements other than conductors, and when reference is made to two elements coupled together, this signifies that these two elements can be connected or they can be coupled via one or more other elements.

In the following description, where reference is made to absolute position qualifiers, such as the terms “front”, “back”, “top”, “bottom”, “left”, “right”, etc., or relative position qualifiers, such as the terms “top”, “bottom”, “upper”, “lower”, etc., or orientation qualifiers, such as “horizontal”, “vertical”, etc., reference is made unless otherwise specified to the orientation of the drawings.

Unless specified otherwise, the expressions “about”, “approximately”, “substantially”, and “in the order of” signify plus or minus 10% or 10°, preferably of plus or minus 5% or 5°.

FIG. 1 shows, schematically and in the form of blocks, an example of a digital-to-analog converter 1 of the type to which the described embodiments apply.

Converter 1 comprises an input 100 configured to receive a digital control code Cin. As an example, code Cin comprises N bits, with N being an integer, for example, greater than or equal to 3. For example, input code Cin comprises N bits Cin_i, with i an index ranging from 0 to N−1, the weight of bits Cin_i increasing with index i. For example, in FIG. 1, N is equal to 8.

Converter 1 comprises an output 102 configured to deliver an analog output signal, for example a voltage Vout. As an example, converter 1 is of resistive type.

The state, or value, of each bit of code Cin determines the value of voltage Vout.

For each of the N bits Cin_i, converter 1 comprises a voltage control circuit 104. Each of the N circuits 104 is configured to receive a bit Cin_i different from the bits Cin_i received by the other circuits 104, and to partly determine the value of output voltage Vout as a function of the value of the bit Cin_i that it receives. As an example, each circuit 104 has an output coupled, for example connected, to the output 102 of converter 1.

As an example, circuits 104 are all identical. As an alternative example, converter 1 may comprise at least two different circuits 104.

For each bit Cin_i, converter 1 comprises a transmission path configured to receive the bit Cin_i received by the input 100 of converter 1, and to transmit it to the circuit 104 corresponding to this bit Cin_i.

In the example of FIG. 1, converter 1 comprises a binary-type digital-to-analog converter 106 and a thermometric-type digital-to-analog converter 108. As an example, the two converters 106 and 108 are connected in parallel between input 100 and output 102 of converter 1. As an example, both converters 106 and 108 are resistive digital-to-analog converters. For example, converter 106 is based on a resistive R2R-type architecture, and converter 108 is based on a resistive architecture of voltage dividing bridge type.

Converter 106 is controlled by part of the bits of code Cin, and converter 108 is controlled by the other part of the bits of code Cin. Converter 106 comprises the circuits 104 which receive the bits of code Cin controlling converter 106, converter 108 comprising the other circuits 104, that is, the circuits 104 which receive the bits of code Cin controlling converter 108. Preferably, binary-type converter 106 is configured to receive the least significant bit(s) of code Cin, for example the bits Cin_i of weight i included in a range from 0 to x, with x a positive integer smaller than or equal to N−2, thermometric-type converter 108 then being configured to receive the most significant bits of code Cin, for example the bits of weight i included in a range from x+1 to N−1.

In the converter 1 comprising converter 106 and converter 108, when code Cin changes from a first code to a second code, the output voltage may exhibit a voltage glitch due to the difference in response times of the two converters 106 and 108 with respect to the change of code Cin.

Indeed, thermometric converter 108 generally has a faster response time than converter 106. In other words, when code Cin changes, the variation in the value of the output voltage resulting from the code change and caused by converter 108 occurs before the variation in the output voltage value resulting from the code change and caused by converter 106.

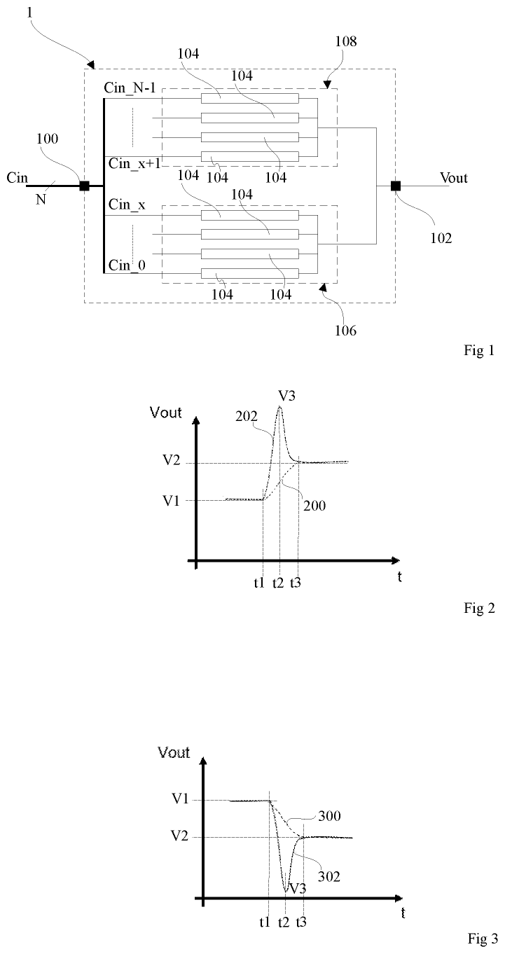

FIG. 2 illustrates by means of curves 200 and 202 an example of a problematic operation of the converter of FIG. 1 during a change of code Cin. Curve 200 illustrates the expected operation of converter 1, and curve 202 illustrates the practical operation of converter 1.

In the example of FIG. 2, at a time t1, code Cin changes from a first code controlling a first value V1 of voltage Vout, to a second code controlling a second value V2 of voltage Vout, value V2 being greater than value V1 in the example of FIG. 2. Preferably, the two codes are successive codes, that is, they control two immediately successive values V1 and V2 from among the values of voltage Vout that converter 1 can deliver.

In the example of FIG. 2, the number N of bits is equal to 6 and x is equal to 3. In this case, converter 106 receives the least significant bits Cin_0, Cin_1, Cin_2, and Cin_3, and converter 108 receives the most significant bits Cin_4 and Cin_5

As an example, the first code is 001111 and the second code is 010000. In other words, for the first code, converter 108 receives only ‘0’ bits and converter 106 receives only ‘1’ bits, and for the second code, converter 108 receives one ‘0’ bit and one ‘1’ bit, and converter 106 receives only ‘0’ bits.

In the case of curve 200, voltage Vout increases from time t1 to a time t3, from value V1 to value V2, but without exhibiting any glitch of voltage Vout.

In the case of curve 202, following the change in code Cin at time t1, the change in voltage Vout controlled by converter 108 occurs before that controlled by converter 106. Thus, at a time t2 between times t1 and t2, voltage Vout takes a value V3 corresponding to a third code Cin equal to 011111, value V3 being greater than values V1 and V2. As a result, at time t3, voltage Vout has a positive (or increasing) voltage pulse and takes value V3. In other words, between times t1 and t2, voltage Vout increases from value V1 to value V3. Then, between times t3 and t2, the change in voltage Vout caused by converter 106 occurs, after that controlled by converter 108, and voltage Vout decreases from value V3 until it reaches value V2 at time t3.

The positive voltage glitch V3 during the change in code Cin from the first code corresponding to the first value V1 to the second code corresponding to the second value V2 greater than value V1 is not desirable. For example, such a pulse is not desirable when converter 1 is part of a system 4 such as illustrated in FIG. 4.

FIG. 4 shows, schematically and in the form of blocks, an example of an electronic system 4 comprising digital-to-analog converter 1.

Converter 1 is configured to deliver voltage Vout at a value determined by the code Cin that it receives.

System 4 further comprises a comparator 400 configured to compare voltage Vout with a reference voltage Vref, for example when converter 1 is controlled by codes Cin to generate an increasing voltage ramp Vout. Comparator 400 delivers a binary output signal Cmp indicating the result of this comparison.

For example, a first input of comparator 400, for example the non-inverting input, receives voltage Vout, and a second input of comparator 400, for example the inverting input of comparator 400, receives voltage Vref.

As an example, although this is not illustrated in FIG. 4, system 4 comprises a control circuit configured to supply digital codes Cin to converter 1, these codes Cin being, for example, successive and configured so that voltage Vout is an increasing voltage ramp.

FIG. 5 illustrates by means of curves an example of a problematic operation of the system 4 of FIG. 4, comprising the converter 1 of FIG. 1.

FIG. 5 more particularly illustrates the case where code Cin changes from a first code controlling a value V1 of voltage Vout, to a second code controlling a value V2 greater than V1 of voltage Vout, and where, as described in relation with FIG. 2, this change in code Cin causes a positive glitch of voltage Vout, which then increases to a value V3 greater than values V1 and V2, before decreasing to value V2. In this example, voltage Vref is between values V3 and V2.

Thus, during the voltage glitch of value V3, the output Cmp of comparator 400 switches, in this example to a high state, to indicate that voltage Vout is greater than Vref, before switching again, in this example to a low state, to indicate that voltage Vout is lower than Vref. However, in the expected operation of converter 1 (curve 200 of FIG. 2), voltage Vout does not exceed value Vref during the change in code Cin, controlling the transition of voltage Vout from value V1 to value V2. The brief switching of signal Cmp during the glitch of voltage Vout is thus not expected and may cause a malfunction of system 4, for example when signal Cmp controls a motor or a timer of system 4.

Although an example of an unwanted glitch of voltage Vout resulting from a change in code Cin from a first code controlling a value V1 of voltage Vout to a second code controlling a value V2 of voltage Vout has been described hereabove, in the case where value V2 is greater than value V1, an unwanted glitch of voltage Vout may also occur when value V1 is greater than value V2, as illustrated in FIG. 3.

FIG. 3 illustrates by means of curves 300 and 302 an example of a problematic operation of the converter of FIG. 1 during a change in code Cin. Curve 300 illustrates the expected operation of converter 1, and curve 302 illustrates the practical operation of converter 1.

In the example of FIG. 3, at time t1, code Cin changes from a first code controlling a first value V1 of voltage Vout, to a second code controlling a second value V2 of voltage Vout, value V2 being lower than value V1. Preferably, the two codes are successive codes, that is, they control two immediately successive values among the values of voltage Vout that converter 1 can supply, or also the two codes are immediately successive codes among all the codes Cin that converter 1 can receive.

In the example of FIG. 3, the number N of bits is equal to 6 and x is equal to 3. In this case, converter 106 receives the least significant bits Cin_0, Cin_1, Cin_2, and Cin_3, and converter 108 receives the most significant bits Cin_4 and Cin_5.

As an example, the first code is 010000 and the second code is 001111. In other words, for the first code, converter 108 receives a ‘0’ bit and a ‘1’ bit, and converter 106 only receives ‘0’ bits, and for the second code, converter 108 only receives ‘0’ bits and converter 106 only receives ‘1’ bits.

In the case of curve 300, voltage Vout decreases from time t1 to time t3, from value V1 to value V2, but without exhibiting any glitch of voltage Vout.

In the case of curve 302, following the change of code Cin at time t1, the change in voltage Vout controlled by converter 108 occurs before that controlled by converter 106. Thus, at a time t2 between times t1 and t2, voltage Vout takes a value V3 corresponding to a third code Cin equal to oooooo, value V3 being lower than values V1 and V2. As a result, at time t3, voltage Vout exhibits a negative (or decreasing) voltage pulse and takes value V3. In other words, between times t1 and t2, voltage Vout decreases from value V1 to value V3. Then, between instants t3 and t2, the change in voltage Vout caused by converter 106 occurs, after that controlled by converter 108, and voltage Vout increases from value V3 until it reaches value V2 at time t3.

The negative voltage glitch V3 during the change of code Cin from the first code corresponding to the first value V1 to the second code corresponding to the second value V2 lower than value V1 is not desirable. For example, such a pulse is not desirable when converter 1 forms part of a system 4 such as shown in FIG. 4 and voltage Vref is between values V3 and V2. Indeed, this may lead to the unwanted switching of signal Cmp resulting from the glitches of voltage Vout. As an example, in this case, the circuit for controlling system 4 delivers successive codes Cin so that voltage Vout is a decreasing voltage ramp.

Further, although unwanted glitches occurring during a change of code Cin have been described hereabove for the case where converter 1 comprises a binary converter 106 and a thermometric converter 108, unwanted glitches may also occur in a converter 1 of binary type only, that is, converter 108 is omitted, or in a converter 1 of thermometric type only, that is, converter 106 is omitted. Indeed, such glitches may result not only from a difference in response time between circuits 104, but also from an imbalance in the bit transmission path lengths from input 100 to circuits 104 when these circuits are effectively implemented.

To avoid unwanted voltage glitches during a change in code Cin, it is here provided to add transmit circuits on the bit transmission paths from input 100 to circuit 104, and that the time of transmission of a bit by each transmit circuit depends on the change in code Cin and is configured so that the voltage pulse Vout generated during the change in code Cin has a desired polarity. In other words, each transmit circuit has a transmission time which is configurable or variable as a function of the change in code Cin occurring on converter input 100, so that the voltage pulse Vout generated during the change in code Cin has a desired polarity.

In other words, it is here provided to add transmit circuits on the paths of transmission of bits Cin_0 to Cin_N and that these transmit circuits, that is, the transmission times that they introduce, are configured so that a pulse of voltage Vout during the change has a positive (increasing) or negative (decreasing) polarity which is selected or desired, for example to avoid malfunctions in a system comprising the converter.

Still in other words, during a change in code Cin from a first code controlling a first value V1 to a second code controlling a value V2, the transmit circuits are configured so that the voltage control circuits Vout which used to receive the bits of the first code Cin first receive a third code (or intermediate code) causing a voltage pulse of desired polarity, before receiving the bits of the second code. The pulse of desired polarity then occurs between a time at which the voltage control circuits receive the bits of the first code Cin and a time at which these circuits receive the bits of the second code Cin.

For example, taking the example of FIGS. 4 and 5, providing transmission times such that the voltage pulse has a negative polarity, that is, value V3 is smaller than values V1 and V2, enables to eliminate the unwanted switching of signal Cmp in FIG. 5. As another example, in the case of system 4 and of a value V1 greater than value V2, providing transmission times such that the voltage pulse has a positive polarity, that is, value V3 is greater than values V1 and V2, enables to eliminate an unwanted switching of signal Cmp.

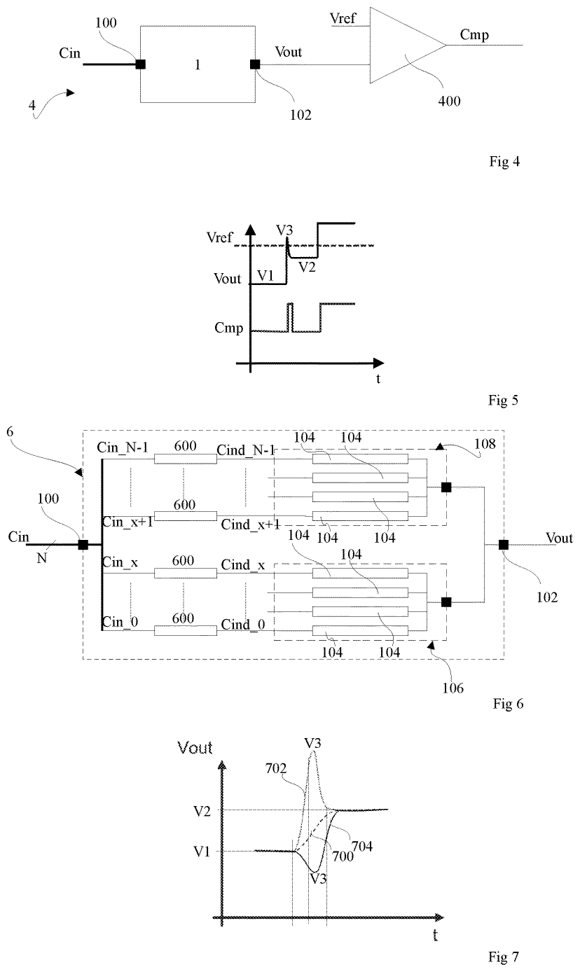

FIG. 6 shows, schematically and in the form of blocks, an example of embodiment of a digital-to-analog converter 6.

Converter 6 has many features in common with converter 1, and only the differences between these two converters are here detailed. Thus, unless otherwise indicated, all that has been indicated for converter 1 applies to converter 6.

As compared with converter 1, for each bit Cin_i, or, in other words, for each path of transmission of a bit Cin_i from input 100 to a corresponding circuit 104, converter 6 comprises a transmit circuit 600.

In FIG. 6, for each path of transmission of a bit Cin_i from input 100 to a corresponding circuit 104, there is called Cin_i the bit received by circuit 600 from input 100, that is, the bit received by input 100, and Cind_i is the corresponding bit supplied by this circuit 600 to the corresponding circuit 104, that is, the bit transmitted by circuit 600 to the corresponding circuit 104. This enables to differentiate the bit received by circuit 600 and the bit, delayed or not with respect to the other bits transmitted to circuits 104, supplied or transmitted by circuit 600 to the corresponding circuit 104.

Each circuit 600 is configured to control the time of transmission of a bit via the transmission path comprising this circuit 600. In other words, each circuit 600 is configured to control the time of transmission of a bit that this circuit 600 transmits from input 100 to a corresponding circuit 104.

More particularly, circuits 600 are configured so that, for at least one change in digital code Cin from a first code controlling a first value V1 of voltage Vout to a second code controlling a second value V2 of voltage Vout, the circuits 104 receive, between the first and second codes, a third code, or intermediate or transient code, causing a voltage pulse of desired polarity.

According to an embodiment, the first and second codes are immediately successive codes from the set of codes Cin that circuit 6 can receive. In other words, the two codes control two immediately successive values V1 and V2 from among the values of the voltage Vout that converter 6 can supply.

According to an embodiment, the change in digital code Cin from a first code controlling a first value V1 of voltage Vout to a second code controlling a second value V2 of voltage Vout for which circuits 600 control the bit transmission times so that circuits 104 receive, between the first and second codes Cin, a third transient code causing a voltage pulse of targeted polarity, comprises each change in code Cin, preferably between two successive codes Cin, involving a change in value of at least two bits between the first code and the second code.

As a variant, in an embodiment where converter 6 comprises the two converters 106 and 108, the change in digital code Cin from a first code controlling a first value V1 of voltage Vout to a second code controlling a second value V2 of voltage Vout for which circuits 600 control the bit transmission times so that circuits 104 receive, between the first and second codes Cin, a third transient code causing a voltage pulse of targeted polarity, only comprises changes in code Cin, preferably between two successive codes Cin, involving a change of value of at least two bits between the first code and the second code with one of these at least two bits which corresponds to the least significant bit received by converter 108.

Indeed, the inventors have observed that these changes in code Cin were likely to generate problematic voltage glitches, for example positive voltage glitches when the code change corresponds to a value V1 lower than voltage V2, and negative voltage glitches when the code change corresponds to a value V1 higher than voltage V2. When a single bit changes value between the first and second code of a change in code Cin, there can be no glitches of voltage Vout.

According to an embodiment, each time code Cin changes from a first code to a second code, involving a change in the value of at least two bits between the first code and the second code, circuits 600 are configured so that the bits having weights lower than the weight of the most significant of the at least two bits are transmitted faster to the voltage control circuits than the other bits of the code.

According to an embodiment, at each change in code Cin from a first code to a second code involving a change in value of at least two bits between the first code and the second code, circuits 600 are configured so that:
the third code supplied to circuits 104 between the first and second codes has least significant bits which correspond to the bits having weights lower than the weight of the most significant of the at least two bits;
the third code has most significant bits corresponding to bits having weights greater than or equal to the weight of the most significant of the at least two bits;
the least significant bits of the third code have values equal to those of the corresponding bits (that is, of same weight) of the second code; and
the most significant bits of the third code have values equal to those of the corresponding bits (that is, of same weight) of the first code.

Indeed, the inventors have observed that the provision of a third transient code such as defined hereabove enables to generate, for example, voltage pulses having a negative desired polarity when the code change corresponds to a value V1 lower than the voltage V2, and voltage pulses having a positive desired polarity when the code change corresponds to a value V1 higher than voltage V2. An example of such an embodiment is illustrated in Tables 1 and 2 hereafter.

In other words, according to a first embodiment, when the first value V1 is lower than the second value V2, circuits 600 are configured so that the transient code supplied to circuits 104 by circuits 600 causes a voltage pulse having a negative polarity, and, according to a second embodiment combined or not with the first embodiment, when the first value V1 is greater than the second value V2, circuits 600 are configured so that the transient code supplied to circuits 104 by circuits 600 causes a voltage pulse having a positive polarity.

In Tables 1 and 2 hereafter, the number N of bits Cin is equal to 5, and x is equal to 3. In other words, converter 106 comprises four circuits 104 receiving the respective bits Cind_0, Cind_1, Cind_2, and Cind_3, and converter 108 comprises a single circuit 104 receiving bit Cind_4.

In these tables, each line corresponds to a change in input code Cin from a first code (left-hand column) to an immediately successive second code (right-hand column). In these tables, the central left-hand column corresponds to the third transient code Cind received by circuits 104 between the first and second codes when the converter comprises circuits 600, and the central right-hand column corresponds to one or more codes corresponding to voltage glitch values that might occur on voltage Vout in the absence of circuits 600.

Table 1 illustrates the case where each change from the first code to the second code Cin corresponds to a control by circuit 6 to generate an increasing voltage ramp Vout. Only changes in code Cin corresponding to the beginning of the ramp and the change in code Cin from the first code 01111 to the second code 10000 have been shown.

TABLE 1

| First | Transient | Code corresponding | Second |
|---|---|---|---|
| code Cin | code Cind | to a glitch | code Cin |
| 00000 | — | — | 00001 |
| 00001 | 00000 | 00011 | 00010 |
| 00010 | — | — | 00011 |
| 00011 | 00000 | 00111 or 00110 or | 00100 |
| | | 00101 | |
| 00100 | — | — | 00101 |
| 00101 | 00100 | | 00110 |
| 00110 | — | — | 00111 |
| 00111 | 00000 | 01001 or 01010 or | 01000 |
| | | 01011 or 01100 or | |
| | | 01101 or 01110 or | |
| | | 01111 | |
| 01111 | 00000 | 10001 or 10010 or | 10000 |
| | | 10011 or 10100 or | |
| | | 10101 or 10110 or | |
| | | 10111 or 11000 or | |
| | | 11001 or 11010 or | |
| | | 11011 or 11100 or | |
| | | 11101 or 11110 or | |
| | | 11111 | |

As an example, as illustrated in Table 1 hereabove, during the change in code Cin from a first code 00001 corresponding to a first value V1 of voltage Vout to a second code 00010 corresponding to a value V2 of voltage Vout greater than value V1, in the absence of circuits 600, voltage Vout may take a positive glitch value V3 which corresponds to code Cin=00011 and which is greater than value V2. This is the case, for example, if the change in voltage Vout controlled by the circuit 104 receiving bit Cin_1 occurs before that controlled by circuit 104 receiving bit Cin_0. On the other hand, with circuits 600, circuits 104 receive a third code ooooo between the first code 00001 and the second code 00010, and this third transient code causes a voltage pulse of desired negative polarity having a value V3 lower than values V1 and V2.

In the above example, the most significant bit which changes value between the first and second codes is bit Cin_1. The third code then has a single least significant bit Cind_0, which corresponds to the bit of lower weight than bit Cin_1, and has most significant bits Cind_1 to Cind_4, which correspond to the bits Cin_1 to Cin_4 having a weight greater than or equal to that of bit Cin_1. Further, the least significant bit Cind_0 of the third code has the value of the bit Cin_0 of the second code, that is, bit Cind_0 has value ‘0’, and the most significant bits Cind_1 to Cind_4 of the third code have values equal to the respective bits Cin_1 to Cin4 of the first code, that is, Cind_1=‘0’, Cind_2=‘0’, Cind_3=‘0’, and Cind_4=‘0’.

As another example, as illustrated in Table 1 hereabove, during the change in code Cin from a first code 01111 corresponding to a first value V1 of voltage Vout, to a second code 10000 corresponding to a value V2 of voltage Vout greater than value V1, in the absence of circuits 600, voltage Vout may take a positive glitch value V3 corresponding to code Cin=11111 which is greater than value V2. This is the case, for example, due to the fact that converter 108 has a shorter response time than converter 106. On the other hand, with circuits 600, circuits 104 receive a third code 00000 between the first code 01111 and the second code 10000, and this third transient code causes a voltage pulse of negative desired polarity having a value V3 lower than values V1 and V2.

In this other example, the most significant bit which changes value between the first and second codes is bit Cin_4. The third code then has least significant bits Cind_0 to Cind_3, which correspond to the least significant bits of bit Cin_4, and a single most significant bit Cind_4, which corresponds to the most significant bit of bit Cin_4. Further, the least significant bits Cind_0, Cind_1, Cind_2, and Cind_3 of the third code have the values ‘0’, ‘0’, ‘0’ and ‘0’ respectively of the bits Cin_0, Cin_1, Cin_2, and Cin_3 of the second code, and the most significant bit Cind_4 of the third code has a value ‘0’ of the bit Cin_4 of the first code.

FIG. 7 illustrates by means of curves 700, 702, 704 an example of operation of the converter 6 of FIG. 6 as compared with the converter 1 of FIG. 1, in the case of a change in code Cin corresponding to one or the other of the two above examples. Curve 700 illustrates the expected operation of converter 1, curve 702 illustrates the practical operation of converter 1, and curve 704 illustrates the operation of converter 6.

As illustrated in FIG. 7, in the case of the practical operation of converter 1 (curve 702), voltage Vout has a positive voltage pulse reaching a value V3 greater than values V1 and V2, while in the case of the practical operation of converter 6 (curve 704), due to the transmission times controlled by circuits 600, circuits 104 receive, between the first code corresponding to value V1 and the second code corresponding to value V2, a third transient code corresponding to a pulse of negative desired polarity which reaches a value V3 lower than values V1 and V2.

Table 2 illustrates the case where each change from the first code to the second code Cin corresponds to a control by circuit 6 to generate a decreasing voltage ramp Vout. Only the changes in code Cin corresponding to the end of the ramp of voltage Vout and the change in code Cin from the first code 10000 to the second code 01111 have been shown.

TABLE 2

| First | Transient | Code Cin corresponding | Second |
|---|---|---|---|
| Cin code | code Cind | to a glitch | code Cin |
| 10000 | 11111 | 00000 or 00001 or | 01111 |
| | | 00010 or 00011 or | |
| | | 00100 or 00101 or | |
| | | 00110 or 00111 or | |
| | | 01000 or 01001 or | |
| | | 01010 or 01011 or | |
| | | 01100 or 01101 or | |
| | | 01110 | |
| 01000 | 01111 | 00000 or 00001 or | 00111 |
| | | 00010 or 00011 or | |
| | | 00100 or 00101 or | |
| | | 00110 | |
| 00111 | — | — | 00110 |
| 00110 | 00111 | | 00101 |
| 00101 | — | — | 00100 |
| 00100 | 00111 | 00010 or 00001 00000 | 00011 |
| 00011 | — | — | 00010 |
| 00010 | 00011 | 00000 | 00001 |
| 00001 | — | — | 00000 |

As an example, as illustrated in Table 2 hereabove, during the change in code Cin from a first code 10000 corresponding to a first value V1 of voltage Vout to a second code 01111 corresponding to a value V2 of voltage Vout lower than value V1, in the absence of circuits 600, voltage Vout may take a negative parasitic pulse value V3 which corresponds to code Cin=00000 and which is lower than value V2. This is the case, for example, due to the fact that converter 108 has a lower response time than that of converter 106. On the other hand, with circuits 600, circuits 104 receive a third code 11111 between the first code 10000 and the second code 01111, and this third transient code causes a voltage pulse of positive desired polarity having a value V3 greater than values V1 and V2.

In the above example, the most significant bit which changes value between the first and second codes is bit Cin_4. The third code has least significant bits Cind_0 to Cind_3, which correspond to the least significant bits of bit Cin_4, and has a single most significant bit Cind_4, which corresponds to the most significant bit of bit Cin_4. Further, the least significant bits Cind_0, Cind_1, Cind_2, and Cind_3 of the third code have the respective values ‘1’, ‘1’, ‘1’, and ‘1’ of the respective bits Cin_0, Cin_1, Cin_2, and Cin_3 of the second code, and the most significant bit Cind_4 of the third code has the value ‘1’ of the bit Cin4 of the first code.

As another example, as illustrated in Table 2 hereabove, during the change in code Cin from a first code 00010 corresponding to a first value V1 of voltage Vout to a second code 00001 corresponding to a value V2 of voltage Vout lower than value V1, in the absence of circuits 600, voltage Vout may take a negative parasitic pulse value V3 corresponding to code Cin=00000 which is lower than value V2. This is the case, for example, if the change in voltage Vout controlled by circuit 104 receiving bit Cin_1 occurs before that controlled by the circuit 104 receiving bit Cin_0. On the other hand, with circuits 600, circuits 104 receive a third code 00011 between the first code 00010 and the second code 00001, and this third transient code causes a voltage pulse of desired positive polarity having a value V3 greater than values V1 and V2.

In this other example, the most significant bit which changes value between the first and second codes is bit Cin_1. The third code then has a single least significant bit Cind_0, which corresponds to the least significant bit of bit Cin_1, and has most significant bits Cind_1 to Cind_4 which correspond to the most significant bits of bit Cin_1. Further, the least significant bit Cind_0 of the third code has the value ‘1’ of the bit Cin_0 of the second code, and the most significant bits Cind_1, Cind_2, Cind_3, and Cind_4 of the third code have the respective values ‘1’, ‘0’, ‘0’, and ‘0’ of the respective bits Cin_1, Cin_2, Cin_3, and Cin_4 of the first code.

According to the above, replacing converter 1 with converter 6 in the system 4 of FIG. 4 enables to eliminate any unwanted switching of signal Cmp which results from glitches of voltage Vout when system 4 is implemented with converter 1.

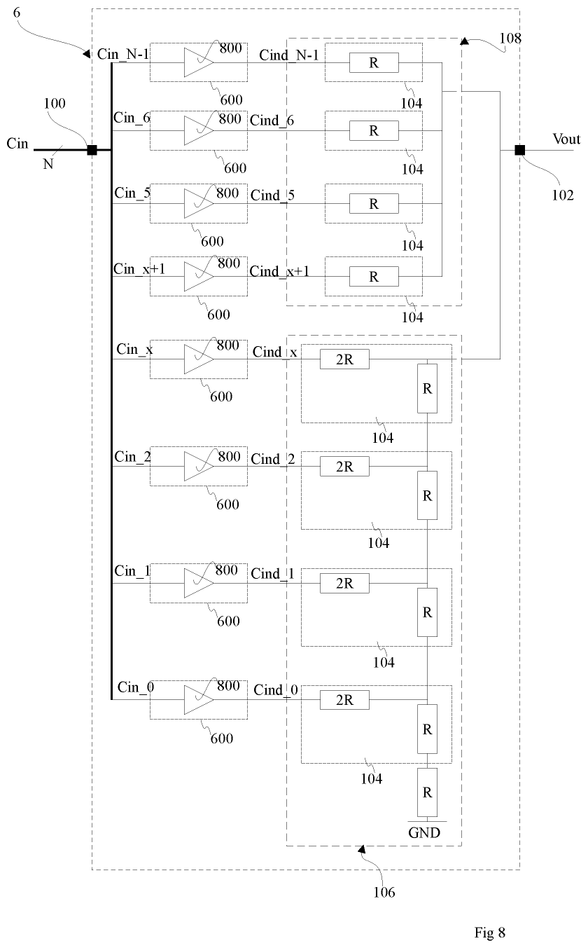

FIG. 8 shows, schematically and in the form of blocks, a more detailed example of embodiment of the digital-to-analog converter of FIG. 6. In this example, the number N of bits in code Cin is equal to 8 and x is equal to 3.

FIG. 8 shows in more detailed fashion an example of implementation of the circuits 104 of thermometric converter 108.

In this example, each circuit 104 of converter 108 comprises a resistor R of resistance value Rval. Resistor R has one terminal coupled, for example connected, to the output of a corresponding circuit 600 for receiving a bit Cind_i, and another terminal coupled, for example connected, to the output 102 of converter 6.

Further, FIG. 8 shows in more detailed fashion an example of implementation of the circuits 104 of thermometric converter 108.

In this example, irrespective of the way in which converter 108 is implemented, converter 106 has an R2R-type structure. Thus, each circuit 104 of converter 106 comprises a resistor 2R having a value equal to twice Rval and a resistor R having a value Rval. In each circuit 104 of converter 106, resistor 2R couples the input of this circuit 104 to its output, which is in turn coupled to the output 102 of converter 6. For example, resistor 2R has one terminal connected to the input of circuit 104, and another terminal connected to the output of circuit 104. In each circuit 104 of converter 106 receiving a corresponding bit Cind_i, resistor R couples the output of this circuit 104 to the output of the circuit 104 of converter 106 which receives the bit Cind_i−1 of immediately lower weight, or to a reference potential such as ground GND when bit Cind_i is the least significant bit received by converter 106. Further, the output of circuit 104 which receives the most significant bit Cind_i received by converter 106 is preferably connected to the output 102 of converter 6.

Further, independently of the way in which converters 106 and 108 are implemented, in the example of FIG. 8, each circuit 600 comprises a buffer circuit 800 having a transmission time configurable (or variable) as a function of the change in code Cin occurring on converter input 100, this variable or configurable transmission time being configured so that circuits 600 implement the above-described operation of converter 6.

Thus, although this is not shown in FIG. 8, each circuit 800 preferably comprises at least one control input configured to receive a bit Cin_i having a different weight than the bit Cin_i transmitted by this circuit 800, for example to receive the bit Cin_i−1 of weight immediately lower than that of the bit Cin_i transmitted by this circuit 800.

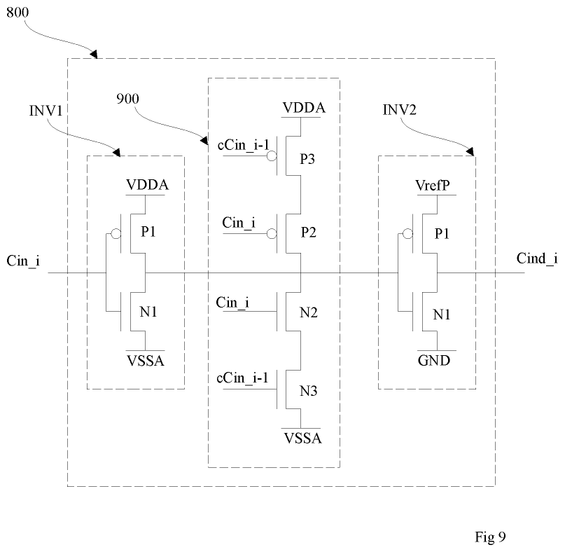

FIG. 9 shows a more detailed example of embodiment of a circuit 800 of the converter 6 of FIG. 8.

Circuit 800 comprises a first inverter INV1 and a second inverter INV2. Inverter INV1 has its input connected to the input of circuit 800 which receives the bit Cin_i to be transmitted, and its output connected to the input of inverter INV2. Inverter INV2 has its input connected to the output of inverter INV1, and its output connected to the output of circuit 800 which delivers the transmitted bit Cind_i.

As an example, the two inverters INV1 and INV2 are identical. For example, each of inverters INV1 and INV2 comprises:
a P-channel metal-oxide-semiconductor (or PMOS) transistor P1 having its source coupled to a high power supply potential, for example a potential VDDA for inverter INV1 and a potential VrefP for inverter INV2, its drain connected to the inverter output, and its gate connected to the inverter input, and
an N-channel MOS (or NMOS) transistor N1 having its source coupled to a low power supply potential, for example, VSSA for inverter INV1 and GND for inverter INV2, its drain connected to the output of the inverter, and its gate connected to the input of the inverter. As an example, potentials VDDA and Vrefp are equal (or identical) and potentials VSSA and GND are equal (or identical).

Circuit 800 further comprises a circuit 900 arranged between inverters INV1 and INV2. Circuit 900 is configured to control the switching speed of the output of inverter INV1, for example based on the value of the bit Cin_i and of the bit Cin_i−1 received by the input of converter 100.

Circuit 900 comprises, for example, two PMOS transistors P2 and P3 in series between high power supply potential VDDA and the output of inverter INV1, and two NMOS transistors N2 and N3 in series between low power supply potential VSSA and the output of inverter INV1. Transistor P3, for example connected to potential VDDA via its source, has its gate controlled by the binary complement of bit Cin_i−1 to which a delay has been applied, this delayed binary complement being designated with reference cCin_i−1 in FIG. 9. Similarly, transistor N3, for example connected to potential VSSA via its source, has its gate controlled by bit cCin_i−1. Transistor P2 has its gate controlled by bit Cin_i, and, similarly, transistor N2 has its gate controlled by bit Cin_i.

Preferably, transistors P3 and P2 have dimensions K times greater than those of transistors P1, with K a positive number greater than 1, and transistors N3 and N2 have dimensions K times greater than those of transistors N1, so that 900 can accelerate the switching of the output of inverter INV1.

As an example, taking the example of Table 1 hereabove, in the case of a code change from a first code 01111 to a second code 10000, the switching to ‘1’ of the output of the inverter INV1 of circuit 800 receiving bit Cin_1 is faster than the switching to ‘0’ of the output of the inverter INV1 of circuit 800 receiving bit Cin_4. This results from the fact that bit cCin_0 (delayed binary complement of bit Cin_0) is still at ‘0’ when bit Cin_1 switches to ‘0’, and bit cCin_3 (delayed binary complement of the Cin_3 bit) is still at ‘0’ when bit Cin_4 switches to ‘1’. Thus, in this example, bit Cind_1 switches to ‘0’ faster than bit Cind_4 switches to ‘1’. The same applies for the circuits 800 receiving bits Cin_0, Cin_2, Cin_3, which enables circuits 104 to receive the third intermediate code 00000 before receiving the second code 10000.

Although this is not illustrated by an example, the circuit 800 of FIG. 9 also enables to implement the operation of the converter 6 described hereabove in the case of a change in code Cin controlling a decrease of voltage Vout.

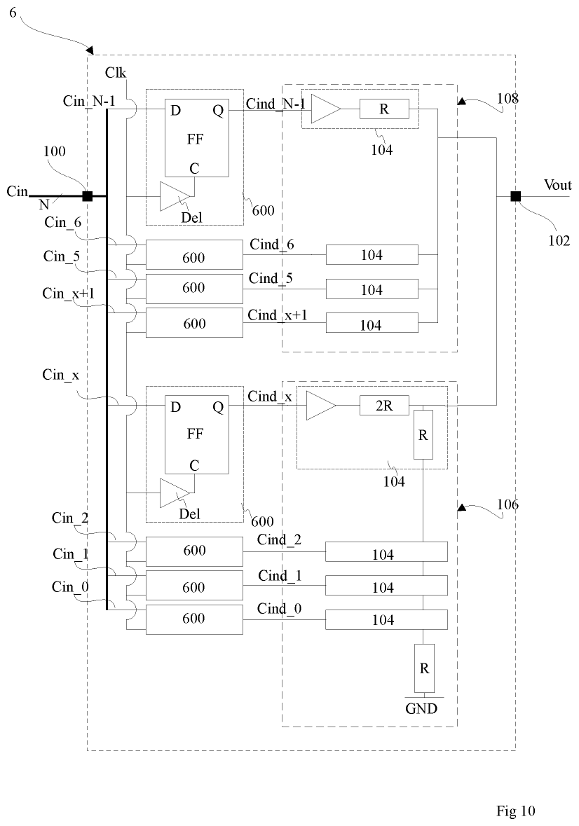

FIG. 10 shows, schematically and in the form of blocks, another more detailed example of embodiment of the digital-to-analog converter of FIG. 6. In the example of FIG. 10, N is equal to 8 and x is equal to 3.

The converter 6 of FIG. 10 differs from that of FIG. 8 by the implementation of its circuits 600.

In FIG. 10, each circuit 600 is configured to receive a clock signal Clk, identical for all circuits 600. Further, each circuit 600 comprises a synchronous flip-flop FF. In each circuit 600, flip-flop FF has a data input D configured to receive the bit Cin_i to be transmitted with this circuit 600, and an output Q configured to deliver the bit Cind_i transmitted by this circuit 104 to the corresponding circuit 104. Further, each circuit 600 comprises a circuit Del configured to transmit the signal Clk received by circuit 600 to a synchronization input C of the flip-flop FF of this circuit 600, with a transmission time determining the time of transmission of a bit by this circuit 600. As an example, for each circuit 600, the time of transmission of signal Clk by circuit Del is variable and determined by a change in code Cin, so as to implement the previously-described operation of converter 6.

Independently of the above-described difference between the converters 6 of FIGS. 8 and 10, the converter 6 of FIG. 10 differs from that of FIG. 8 by the implementation of its circuits 104.

Indeed, in FIG. 10, each circuit 104 of converter 108 comprises a buffer circuit coupling the input of circuit 104 to one terminal of the resistor R of circuit 104, the other terminal of the resistor R of this circuit 104 being coupled, for example connected, to the output 102 of converter 6. Further, in FIG. 10, each circuit 104 of converter 106 comprises a buffer circuit coupling the input of circuit 104 to a terminal of the resistor 2R of circuit 104, the other terminal of the resistor 2R of this circuit 104 being coupled, for example connected, to the output of this circuit 104, which is itself coupled to the output 102 of circuit 6.

Various embodiments and variants have been described. Those skilled in the art will understand that certain features of these various embodiments and variants may be combined, and other variants will occur to those skilled in the art. In particular, although this has not been described or detailed, according to an embodiment, circuits 600 are selectively activatable. In other words, when these circuits are activated, converter 6 operates in such a way as to generate, during a change from a first code to a second code which might lead to a glitch of voltage Vout, a third transient code corresponding to a voltage pulse of desired polarity on voltage Vout, and, when these circuits are deactivated, converter 6 operates as if circuits 600 were absent.

Further, although an example of a converter 6 comprising a converter 106 and a converter 108 has been described, those skilled in the art will be capable of adapting the present disclosure to the case of a converter 6 only comprising converter 106, or to the case of a converter 6 only comprising converter 108.

On the other hand, examples have been described in which circuits 600 adapt the bit transmission times as soon as the change in code Cin involves a change in the value of at least two bits among the bits of code Cin. In the case of a converter 6 comprising a converter 106 and a converter 108, those skilled in the art will be capable of providing circuits 600 which adapt the bit transmission times only when the change in code Cin involves at least one change in the value of a bit received by converter 106 and one change in the value of a bit received by converter 108, for example the least significant bit received by converter 108.

Finally, the practical implementation of the described embodiments and variants is within the abilities of those skilled in the art based on the functional indications given hereabove.

What is claimed is:

1. A digital-to-analog converter comprising:
an input configured to receive a digital code for controlling an output voltage of the digital-to-analog converter;
for each bit of the digital code, a voltage control circuit configured to receive the bit and to partly determine a value of the output voltage based on a value of the bit; and
for each bit of the digital code, a transmission path configured to receive the bit and transmit the bit to a corresponding voltage control circuit;
wherein each transmission path comprises a transmit circuit configured to control a time of transmission of a respective bit via the path; and
wherein the transmit circuits are configured so that, for at least one change in the digital code from a first code controlling a first value of the output voltage to a second code controlling a second value of the output voltage, the voltage control circuits receive, between the first code and the second code, a third code causing a voltage pulse of desired polarity on the output voltage.

2. The digital-to-analog converter according to claim 1, wherein each transmit circuit is selectively activatable.

3. The digital-to-analog converter according to claim 1, wherein the first and second codes are immediately successive codes from a set of digital codes that the digital-to-analog converter is configured to receive.

4. The digital-to-analog converter according to claim 1, further comprising:
a first binary-type digital-to-analog converter configured to be controlled by a first part of the bits of the digital code; and
a second thermometric-type digital-to-analog converter configured to be controlled by an other part of the bits of the digital code.

5. The digital-to-analog converter according to claim 4, wherein:
the first part of the bits is least significant bits of the digital code; and
the other part of the bits is most significant bits of the digital code.

6. The digital-to-analog converter according to claim 1, wherein the at least one change in the digital code comprises each change from the first code to the second code involving a change in value of at least two bits between the first code and the second code.

7. The digital-to-analog converter according to claim 6, wherein the transmit circuits are configured so that, on each code change from the first code to the second code involving a change in value of at least two bits between the first code and the second code, the bit(s) having weights lower than the weight of most significant of the at least two bits are more rapidly transmitted to the voltage control circuits than the other bit(s) of the digital code.

8. The digital-to-analog converter according to claim 6, wherein, at each change in code from the first code to the second code involving a change in value of at least two bits between the first code and the second code:
least significant bit(s) of the third code correspond to the bits having a weight lower than the weight of most significant of the at least two bits;
most significant bit(s) of the third code correspond to the bits having a weight equal to or greater than that of the most significant of the at least two bits;
least significant bit(s) of the third code of the code change have values equal to those of the corresponding bits of the second code; and
most significant bit(s) of the third code of the code change have values equal to those of the corresponding bits of the first code.

9. The digital-to-analog converter according to claim 1, wherein:
the voltage pulse has a positive polarity in response to the first value being greater than the second value; and
the voltage pulse has a negative polarity in response to the first value being lower than the second value.

10. The digital-to-analog converter according to claim 1, wherein each transmit circuit is configured to receive a clock signal and comprises:
a synchronous flip-flop having a data input configured to receive the bit to be transmitted via the path comprising the transmit circuit, and an output supplying the transmitted bit to the corresponding voltage control circuit; and
a first circuit configured to transmit the clock signal to a clock input of the flip-flop with a transmission time determining the time of transmission of the bit by the transmit circuit.

11. The digital-to-analog converter according to claim 1, wherein each transmit circuit comprises:
a first inverter having an output and an input configured to receive the bit to be transmitted via the path comprising the transmit circuit;
a second inverter having an input connected to the output of the first inverter and an output configured to supply the transmitted bit to the corresponding voltage control circuit;
a first p-channel metal-oxide-semiconductor (PMOS) transistor and a second PMOS transistor in series between a high power supply potential and the output of the first inverter; and
a first n-channel MOS (NMOS) transistor and a second NMOS transistor in series between the output of the first inverter and a low power supply potential;
wherein:
a gate of the first PMOS transistor and a gate of the first NMOS transistor are each configured to receive the bit to be transmitted; and
a gate of the second PMOS transistor and a gate of the second NMOS transistor are each configured to receive a delayed binary complement of the bit that has a weight immediately lower than the weight of the bit to be transmitted.

12. An electronic system comprising:
a digital-to-analog converter comprising:
an input configured to receive a digital code for controlling an output voltage of the digital-to-analog converter;
for each bit of the digital code, a voltage control circuit configured to receive the bit and to partly determine a value of the output voltage based on a value of the bit; and
for each bit of the digital code, a transmission path configured to receive the bit and transmit the bit to a corresponding voltage control circuit;
wherein each transmission path comprises a transmit circuit configured to control a time of transmission of a respective bit via the path; and
wherein the transmit circuits are configured so that, for at least one change in the digital code from a first code controlling a first value of the output voltage to a second code controlling a second value of the output voltage, the voltage control circuits receive, between the first code and the second code, a third code causing a voltage pulse of desired polarity on the output voltage; and
a comparator having one input configured to receive a reference voltage, and another input configured to receive the output voltage of the digital-to-analog converter.

13. The electronic system according to claim 12, wherein the electronic system comprises a digital code control circuit configured to supply successive digital codes to the digital-to-analog converter, so that the output voltage of the digital-to-analog converter is an increasing voltage ramp or a decreasing voltage ramp.

14. The electronic system according to claim 12, wherein each transmit circuit is selectively activatable.

15. The electronic system according to claim 12, wherein the first and second codes are immediately successive codes from a set of digital codes that the digital-to-analog converter is configured to receive.

16. The electronic system according to claim 12, wherein the digital-to-analog converter further comprises:
a first binary-type digital-to-analog converter configured to be controlled by a first part of the bits of the digital code; and
a second thermometric-type digital-to-analog converter configured to be controlled by an other part of the bits of the digital code.

17. The electronic system according to claim 12, wherein the at least one change in the digital code comprises each change from the first code to the second code involving a change in value of at least two bits between the first code and the second code.

18. The electronic system according to claim 12, wherein:
the voltage pulse has a positive polarity in response to the first value being greater than the second value; and
the voltage pulse has a negative polarity in response to the first value being lower than the second value.

19. The electronic system according to claim 12, wherein each transmit circuit is configured to receive a clock signal and comprises:
a synchronous flip-flop having a data input configured to receive the bit to be transmitted via the path comprising the transmit circuit, and an output supplying the transmitted bit to the corresponding voltage control circuit; and
a first circuit configured to transmit the clock signal to a clock input of the flip-flop with a transmission time determining the time of transmission of the bit by the transmit circuit.

20. The electronic system according to claim 12, wherein each transmit circuit comprises:
a first inverter having an output and an input configured to receive the bit to be transmitted via the path comprising the transmit circuit;
a second inverter having an input connected to the output of the first inverter and an output configured to supply the transmitted bit to the corresponding voltage control circuit;
a first p-channel metal-oxide-semiconductor (PMOS) transistor and a second PMOS transistor in series between a high power supply potential and the output of the first inverter; and
a first n-channel MOS (NMOS) transistor and a second NMOS transistor in series between the output of the first inverter and a low power supply potential;
wherein:
a gate of the first PMOS transistor and a gate of the first NMOS transistor are each configured to receive the bit to be transmitted; and
a gate of the second PMOS transistor and a gate of the second NMOS transistor are each configured to receive a delayed binary complement of the bit that has a weight immediately lower than the weight of the bit to be transmitted.
